(19) United States
(12) Patent Application Publication
(10) Pub. No.: US 2025/0237694 A1
(43) Pub. Date: Jul. 24, 2025

(54) Failure Diagnosis Circuit, Vibrator Device, And Physical Quantity Sensor

(71) Applicant: SEIKO EPSON CORPORATION, Tokyo (JP)

(72) Inventor: Kiminori NAKAJIMA, Shiojiri (JP)

(21) Appl. No.: 19/033,668

(22) Filed: Jan. 22, 2025

(30) Foreign Application Priority Data
Jan. 23, 2024 (JP) 2024-007914

(51) Int. Cl. G01R 31/28; G01R 19/165

(52) U.S. Cl. CPC G01R 31/2843; G01R 19/16528

(57) ABSTRACT

A failure diagnosis circuit, which performs failure diagnosis on a reference voltage generation circuit, monitors a reference voltage supplied from the reference voltage generation circuit to a first circuit, and diagnoses that the reference voltage generation circuit fails when a state in which the reference voltage is not within a predetermined range continues for a predetermined time.

The present application is based on, and claims priority from JP Application Serial Number 2024-007914, filed Jan. 23, 2024, the disclosure of which is hereby incorporated by reference herein in its entirety.

### BACKGROUND

### 1. Technical Field

The present disclosure relates to a failure diagnosis circuit, a vibrator device, and a physical quantity sensor.

### 2. Related Art

At present, in various systems and electronic devices, physical quantity sensors capable of detecting various physical quantities, such as a gyro sensor for detecting an angular velocity and an acceleration sensor for detecting an acceleration, are widely used. In recent years, for example, in order to construct a system that requires high reliability such as a system mounted on a vehicle, the physical quantity sensor may be required to have a function of diagnosing its own failure. In recent years, in order to construct a system that has high reliability, a physical quantity sensor that outputs detection information of a physical quantity as digital data having high noise resistance is used. Generally, such a physical quantity y sensor includes a physical quantity detection element and a physical quantity detection circuit that generates an analog signal corresponding to a detected physical quantity based on a signal output from the physical quantity detection element, converts the analog signal into a digital signal by an analog-digital conversion circuit, and then performs digital signal processing.

JP A-2021-117072 describes a power supply monitoring circuit that monitors whether a power supply voltage falls within a predetermined range. For example, by applying the power supply monitoring circuit described in JP A-2021-117072, a physical quantity sensor that diagnoses a failure of itself is implemented.

However, in the physical quantity sensor to which the power supply monitoring circuit described in JP A-2021-117072 is applied, when a reference voltage temporarily fluctuates and falls outside the predetermined range due to operations of a signal processing circuit that processes a signal output from a physical quantity detection element or an analog-digital conversion circuit that converts an output signal of the signal processing circuit into a digital signal, it may be erroneously determined that a circuit for generating the reference voltage has failed.

### SUMMARY

One aspect of a failure diagnosis circuit according to the disclosure is a failure diagnosis circuit that performs failure diagnosis on a reference voltage generation circuit, in which
the failure diagnosis circuit monitors a reference voltage supplied from the reference voltage generation circuit to a first circuit, and diagnoses that the reference voltage generation circuit fails when a state in which the reference voltage is not within a predetermined range continues for a predetermined time.

One aspect of a vibrator device according to the disclosure includes:
one aspect of the failure diagnosis circuit.

One aspect physical quantity sensor according to the disclosure includes
one aspect of the failure diagnosis circuit.

### BRIEF DESCRIPTION OF THE DRAWINGS

FIG. 1 is a functional block diagram of a physical quantity sensor according to a first embodiment.

FIG. 2 is a diagram showing a configuration example of a selection circuit and an analog-digital conversion circuit.

FIG. 3 is a diagram showing an example of a channel configuration of time division processing performed by the analog-digital conversion circuit.

FIG. 4 is a diagram showing a configuration example of a part of a reference voltage generation circuit and a failure diagnosis circuit according to the first embodiment.

FIG. 5 is a diagram showing an example of waveforms of various signals when the reference voltage generation circuit does not fail according to the first embodiment.

FIG. 6 is a diagram showing an example of waveforms of various signals when the reference voltage generation circuit fails according to the first embodiment.

FIG. 7 is a flowchart showing an example of a processing procedure of the failure diagnosis circuit according to the first embodiment.

FIG. 8 is a functional block diagram of a physical quantity sensor according to a second embodiment.

FIG. 9 is a diagram showing a configuration example of a part of a reference voltage generation circuit and a failure diagnosis circuit according to the second embodiment.

FIG. 10 is a diagram showing an example of waveforms of various signals when the reference voltage generation circuit does not fail according to the second embodiment.

FIG. 11 is a diagram showing an example of waveforms of various signals when the reference voltage generation circuit fails according to the second embodiment.

FIG. 12 is a flowchart showing an example of a processing procedure of the failure diagnosis circuit according to the second embodiment.

### DESCRIPTION OF EMBODIMENTS

Hereinafter, preferred embodiments of the disclosure will be described in detail with reference to the drawings. The embodiments to be described below do not unduly limit contents of the disclosure described in the claims. Not all configurations described below are necessarily essential components of the disclosure.

Hereinafter, a physical quantity sensor that detects an angular velocity and an acceleration as physical quantities will be described as an example.

### 1. First Embodiment

### 1-1. Configuration of Physical Quantity Sensor

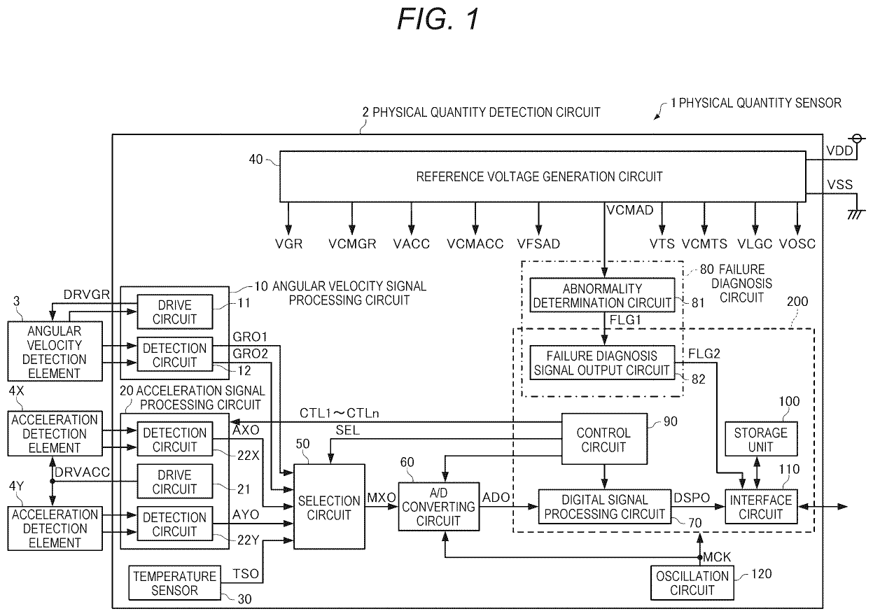

FIG. 1 is a functional block diagram of a physical quantity sensor according to a first embodiment. A physical quantity sensor 1 according to the first embodiment includes a physical quantity detection circuit 2, an angular velocity detection element 3, an acceleration detection element 4X, and an acceleration detection element 4Y.

The acceleration detection elements 4X and 4Y are physical quantity detection elements that detect acceleration as physical quantities. The acceleration detection element 4X detects an acceleration in an X-axis direction, and the acceleration detection element 4Y detects an acceleration in a Y-axis direction orthogonal to the X-axis. For example, each of the acceleration detection elements 4X and 4Y may be an element that has a static capacitance in which a drive electrode and a detection electrode (not shown) are disposed, changes in a charge amount of the static capacitance according to the acceleration, and outputs a signal according to the charge amount. The acceleration detection elements 4X and 4Y may be, for example, micro electro mechanical systems (MEMS) elements.

The angular velocity detection element 3 is a physical quantity detection element that detects an angular velocity as a physical quantity. In the embodiment, the angular velocity detection element 3 detects an angular velocity around a Z-axis orthogonal to the X-axis and the Y-axis. For example, the angular velocity detection element 3 may be an element that includes a vibrator element in which a drive electrode and a detection electrode (not shown) are disposed, changes in a magnitude of vibration of the vibrator element according to the angular velocity, and outputs a signal according to the magnitude of the vibration. The angular velocity detection element 3 may be, for example, an element including a so-called double T-shaped quartz crystal vibrator element including two T-shaped drive vibration arms.

The physical quantity detection circuit 2 includes an angular velocity signal processing circuit 10, an acceleration signal processing circuit 20, a temperature sensor 30, a reference voltage generation circuit 40, a selection circuit 50, an analog-digital conversion circuit 60, a digital signal processing circuit 70, a failure diagnosis circuit 80, a control circuit 90, a storage unit 100, an interface circuit 110, and an oscillation circuit 120. The physical quantity detection circuit 2 may be implemented by, for example, a one-chip integrated circuit. The physical quantity detection circuit 2 may have a configuration obtained by omitting or changing some of the elements, or adding other elements.

The reference voltage generation circuit 40 generates various reference voltages based on a power supply voltage VDD and a ground voltage VSS supplied from the outside of the physical quantity detection circuit 2. In the embodiment, the reference voltage generation circuit 40 generates a power supply voltage VGR and a common voltage VCMGR as reference voltages supplied to the angular velocity signal processing circuit 10. The reference voltage generation circuit 40 generates a power supply voltage VACC and a common voltage VCMACC as reference voltages supplied to the acceleration signal processing circuit 20. The reference voltage generation circuit 40 generates a full scale voltage VFSAD and a common voltage VCMAD as reference voltages supplied to the analog-digital conversion circuit 60. The reference voltage generation circuit 40 generates a power supply voltage VTS and a common voltage VCMTS as reference voltages supplied to the temperature sensor 30. The reference voltage generation circuit 40 generates a power supply voltage VLGC as a reference voltage supplied to the logic circuit 200. The reference voltage generation circuit 40 generates a power supply voltage VOSC as a reference voltage supplied to the oscillation circuit 120.

The oscillation circuit 120 operates based on the power supply voltage VOSC supplied from the reference voltage generation circuit 40, and generates a clock signal MCK. The oscillation circuit 120 may be implemented as, for example, a ring oscillator or a CR oscillation circuit.

The angular velocity signal processing circuit 10 includes a drive circuit 11 and a detection circuit 12, and operates based on the power supply voltage VGR and the common voltage VCMGR supplied from the reference voltage generation circuit 40.

The drive circuit 11 generates a drive signal DRVGR for exciting and vibrating the angular velocity detection element 3, and supplies the drive signal DRVGR to the angular velocity detection element 3. For example, the drive signal DRVGR is a rectangular wave signal in which the power supply voltage VGR is at a high level and the ground voltage VSS is at a low level. The drive circuit 11 receives an oscillation current generated by the excitation vibration of the angular velocity detection element 3, and performs feedback control of an amplitude level of a drive signal such that an amplitude of the oscillation current is kept constant. When the angular velocity around the Z-axis is applied in an excited vibration state, the angular velocity detection element 3 detects the angular velocity and outputs a signal corresponding to the angular velocity. In the embodiment, the signal output from the angular velocity detection element 3 is a differential signal.

The detection circuit 12 is a detection signal generation circuit that generates a detection signal corresponding to the angular velocity around the Z-axis based on an output signal of the angular velocity detection element 3. Specifically, the detection circuit 12 detects an angular velocity component included in the signal output from the angular velocity detection element 3, and generates and outputs an angular velocity detection signal GRO1 having a voltage level corresponding to a magnitude of the angular velocity component. The detection circuit 12 detects a vibration leakage component included in the signal output from the angular velocity detection element 3, and generates and outputs a vibration leakage signal GRO2 having a voltage level corresponding to a magnitude of the vibration leakage component. In the embodiment, the angular velocity detection signal GRO1 and the vibration leakage signal GRO2 are differential signals based on the common voltage VCMGR.

As described above, the angular velocity signal processing circuit 10 is a physical quantity signal processing circuit that outputs the drive signal DRVGR for driving the angular velocity detection element 3 and generates a detection signal corresponding to the angular velocity around the Z-axis, which is one of the physical quantities, based on the output signal of the angular velocity detection element 3.

The acceleration signal processing circuit 20 includes a drive circuit 21, a detection circuit 22X, and a detection circuit 22Y, and operates based on the power supply voltage VACC and the common voltage VCMACC supplied from the reference voltage generation circuit 40. The acceleration signal processing circuit 20 is controlled based on n control signals CTL1 to CTLn supplied from the control circuit 90. n is an integer of 1 or more.

The drive circuit 21 generates a drive signal DRVACC and outputs the drive signal DRVACC to the acceleration detection elements 4X and 4Y to drive the acceleration detection elements 4X and 4Y. For example, the drive signal DRVACC is a rectangular wave signal in which the power supply voltage VACC is at a high level and the ground voltage VSS is at a low level. When an acceleration in an X-axis direction is applied in this state, the acceleration detection element 4X detects the acceleration and outputs a signal corresponding to the acceleration. When an acceleration in a Y-axis direction is applied, the acceleration detection element 4Y detects the acceleration and outputs a signal corresponding to the acceleration. In the embodiment, the signals output from the acceleration detection elements 4X and 4Y are differential signals.

The detection circuit 22X is a detection signal generation circuit that generates a detection signal corresponding to the acceleration in the X-axis direction based on the output signal of the acceleration detection element 4X. Specifically, the detection circuit 22X detects an acceleration component included in the signal output from the acceleration detection element 4X, and generates and outputs an X-axis acceleration detection signal AXO having a voltage level corresponding to a magnitude of the acceleration component. In the embodiment, the X-axis acceleration detection signal AXO is a differential signal based on the common voltage VCMACC.

The detection circuit 22Y is a detection signal generation circuit that generates a detection signal corresponding to the acceleration in the Y-axis direction based on the output signal of the acceleration detection element 4Y. Specifically, the detection circuit 22Y detects an acceleration component included in the signal output from the acceleration detection element 4Y, and generates and outputs a Y-axis acceleration detection signal AYO having a voltage level corresponding to a magnitude of the acceleration component. In the embodiment, the Y-axis acceleration detection signal AYO is a differential signal based on the common voltage VCMACC.

As described above, the acceleration signal processing circuit 20 is a physical quantity signal processing circuit that outputs the drive signal DRVACC for driving the acceleration detection elements 4X and 4Y, generates the detection signal corresponding to the acceleration in the X-axis direction, which is one of the physical quantities, based on the output signal of the acceleration detection element 4X, and generates the detection signal corresponding to the acceleration in the Y-axis direction, which is one of the physical quantities, based on the output signal of the acceleration detection element 4Y.

The temperature sensor 30 detects a temperature based on the power supply voltage VTS and the common voltage VCMTS supplied from the reference voltage generation circuit 40, and outputs a temperature detection signal TSO having a voltage level corresponding to the temperature. The temperature sensor 30 may be, for example, a circuit using a temperature characteristic of a bandgap reference circuit. In the embodiment, the temperature detection signal TSO is a differential signal based on the common voltage VCMTS.

The selection circuit 50 selects and outputs one of the angular velocity detection signal GRO1, the vibration leakage signal GRO2, the X-axis acceleration detection signal AXO, the Y-axis acceleration detection signal AYO, and the temperature detection signal TSO based on a selection signal SEL from the control circuit 90. In the embodiment, an output signal MXO of the selection circuit 50 is a differential signal.

The analog-digital conversion circuit 60 operates based on the full scale voltage VFSAD and the common voltage VCMAD supplied from the reference voltage generation circuit 40. The analog-digital conversion circuit 60 converts the signal MXO, which is an analog signal output from the selection circuit 50, into a digital signal ADO based on various control signals supplied from the control circuit 90, and outputs the digital signal ADO. Specifically, the analog-digital conversion circuit 60 converts the signal MXO, which is a differential signal, into the digital signal ADO using a voltage difference between the full scale voltage VFSAD and the ground voltage VSS as a full scale.

The digital signal processing circuit 70 processes, based on various control signals supplied from the control circuit 90, the digital signal ADO output from the analog-digital conversion circuit 60. For example, the digital signal processing circuit 70 outputs a digital signal DSPO obtained by performing digital filter processing or correction operation processing on the digital signal ADO.

The failure diagnosis circuit 80 performs failure diagnosis on the reference voltage generation circuit 40. Specifically, the failure diagnosis circuit 80 monitors the common voltage VCMAD, which is a reference voltage supplied from the reference voltage generation circuit 40 to the analog-digital conversion circuit 60, and when a state in which the common voltage VCMAD is not within a predetermined range continues for a predetermined time, the failure diagnosis circuit 80 diagnoses that the reference voltage generation circuit 40 fails. The analog-digital conversion circuit 60 is an example of a “first circuit”.

In the embodiment, the failure diagnosis circuit 80 includes an abnormality determination circuit 81 and a failure diagnosis signal output circuit 82.

The abnormality determination circuit 81 determines whether the common voltage VCMAD is abnormal, and outputs an abnormality determination signal FLG1 indicating a determination result. For example, the abnormality determination signal FLG1 may be a flag signal that is at a high level when the common voltage VCMAD is abnormal and is at a low level when the common voltage VCMAD is normal.

The failure diagnosis signal output circuit 82 diagnoses whether the reference voltage generation circuit 40 fails based on the abnormality determination signal FLG1, and outputs a failure diagnosis signal FLG2 indicating a diagnosis result. In the embodiment, the common voltage VCMAD temporarily fluctuates in at least one of a timing at which the analog-digital conversion circuit 60 starts sampling of the output signal MXO of the selection circuit 50 and a timing at which the analog-digital conversion circuit 60 ends the sampling. Therefore, even when the reference voltage generation circuit 40 does not fail, the abnormality determination circuit 81 may temporarily output the abnormality determination signal FLG1 indicating that the common voltage VCMAD is abnormal. Therefore, in order not to erroneously determine that the reference voltage generation circuit 40 fails, the failure diagnosis signal output circuit 82 diagnoses that the reference voltage generation circuit 40 fails when the abnormality determination signal FLG1 continues for a predetermined time and the common voltage VCMAD is abnormal. For example, the failure diagnosis signal FLG2 may be a flag signal that is at a high level when the reference voltage generation circuit 40 fails and is at a low level when the reference voltage generation circuit 40 does not fail.

The control circuit 90 generates and outputs various control signals for controlling operations of the analog-digital conversion circuit 60, the digital signal processing circuit 70, and the like, the selection signal SEL, and the control signals CTL1 to CTLn for controlling the acceleration signal processing circuit 20.

The storage unit 100 includes a nonvolatile memory (not shown), and the nonvolatile memory stores various types of trimming data for the angular velocity signal processing circuit 10, the acceleration signal processing circuit 20, and the like, coefficient data used for processing performed by the digital signal processing circuit 70, and the like. The nonvolatile memory may be implemented by, for example, a metal oxide nitride oxide silicon (MONOS) type memory or an electrically erasable programmable read-only memory (EEPROM). Further, the storage unit 100 may include a register (not shown), and may be implemented such that when the physical quantity detection circuit 2 is powered on, that is, when a voltage of a VDD terminal rises from 0 V to a desired voltage, various types of data stored in the nonvolatile memory is transferred to and held in the register, and various types of data held in the register is supplied to each circuit.

The interface circuit 110 performs processing of outputting the digital signal DSPO and the failure diagnosis signal FLG2 in response to a request from an external device. The interface circuit 110 performs processing of reading and outputting data stored in the nonvolatile memory or the register of the storage unit 100 in response to the request from the external device of the physical quantity detection circuit 2, processing of writing the data received from the external device into the nonvolatile memory or the register of the storage unit 100, and the like. The interface circuit 110 may be, for example, an interface circuit of a serial peripheral interface (SPI) bus or an interface circuit of an inter-integrated circuit (I²C) bus.

The digital signal processing circuit 70, the failure diagnosis signal output circuit 82, the control circuit 90, the storage unit 100, and the interface circuit 110 constitute a logic circuit 200. The logic circuit 200 operates based on the power supply voltage VLGC supplied from the reference voltage generation circuit 40 according to the clock signal MCK.

### 1-2. Configuration of Selection Circuit and Analog-Digital Conversion Circuit

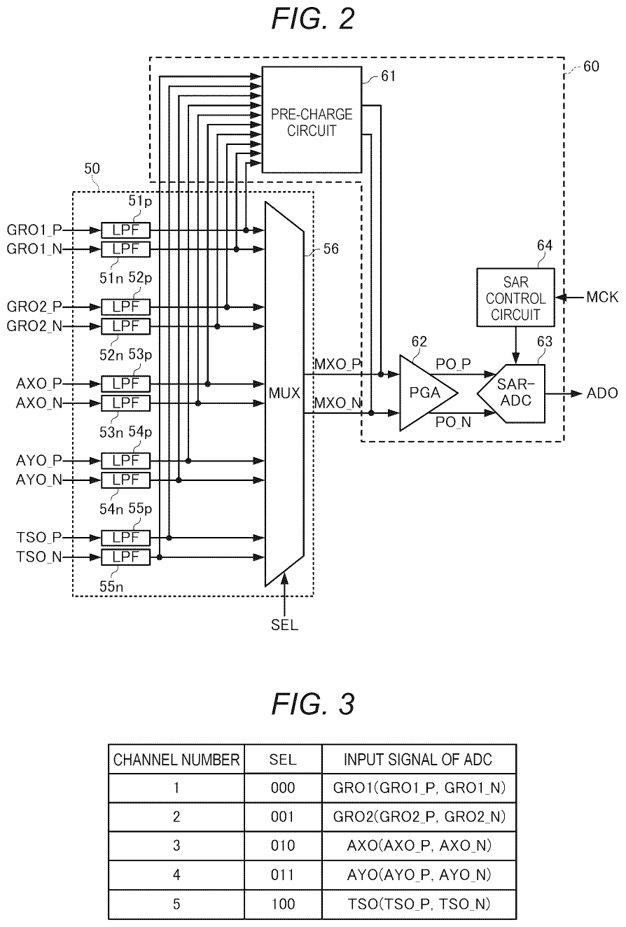

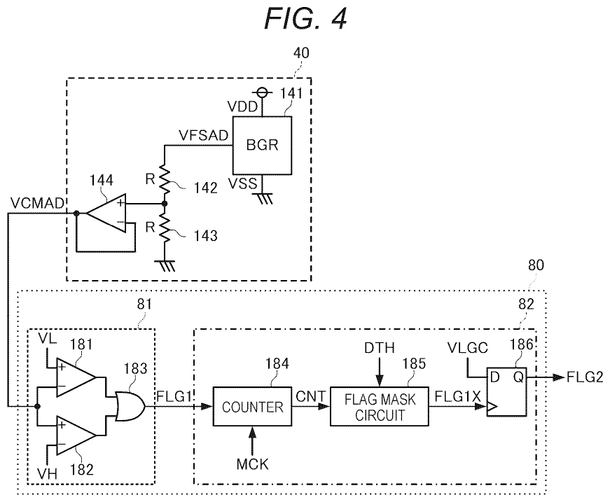

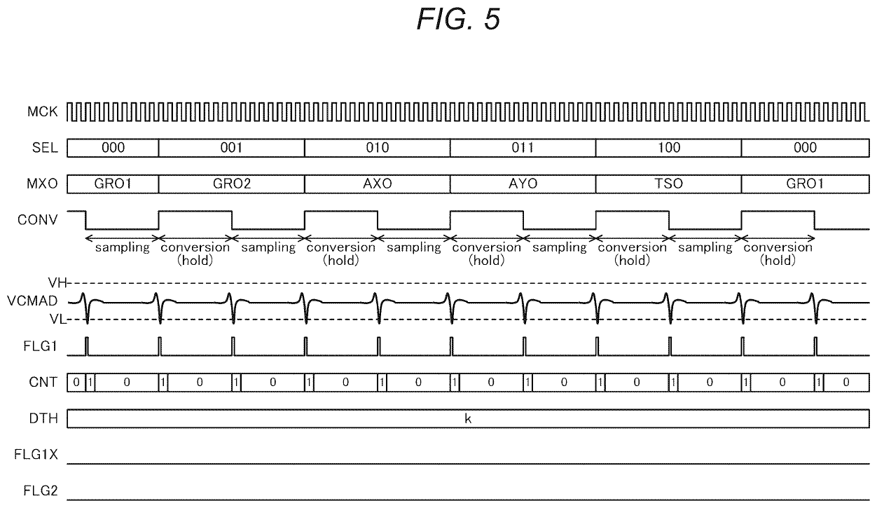

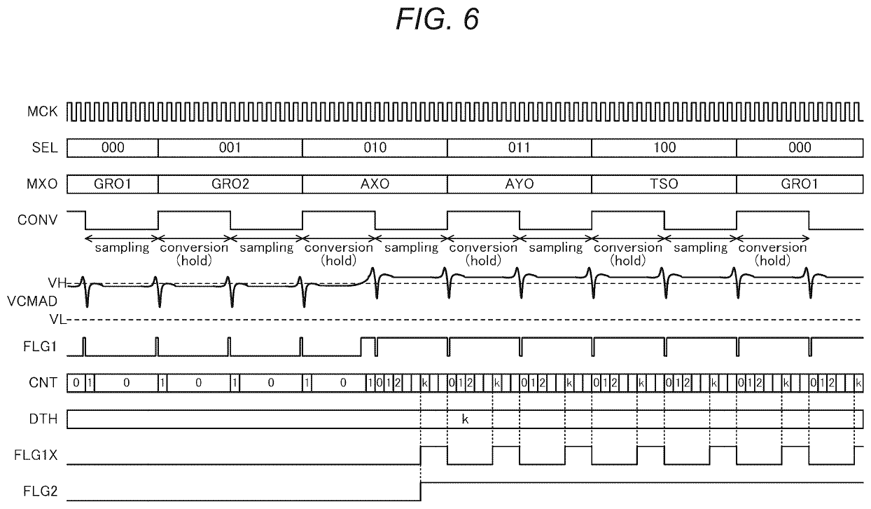

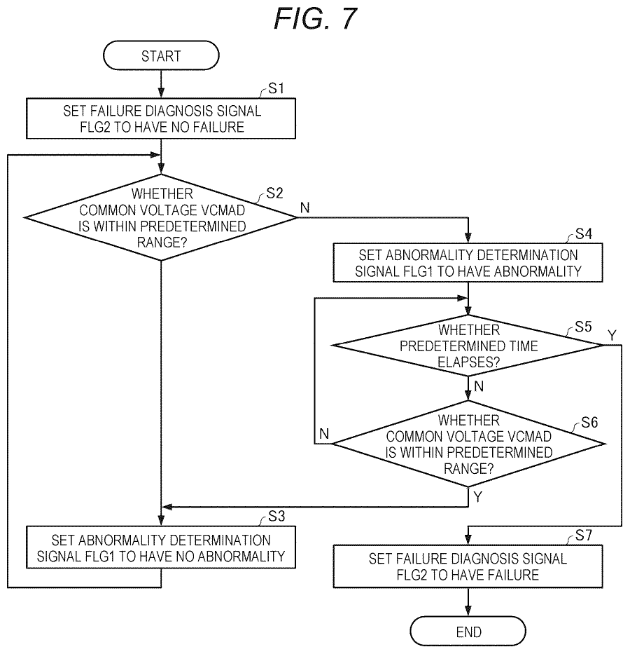

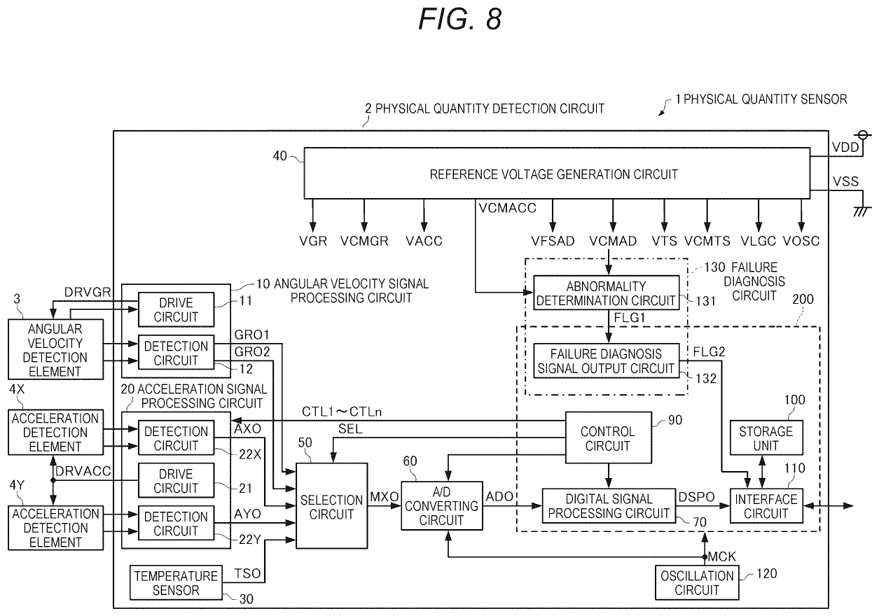

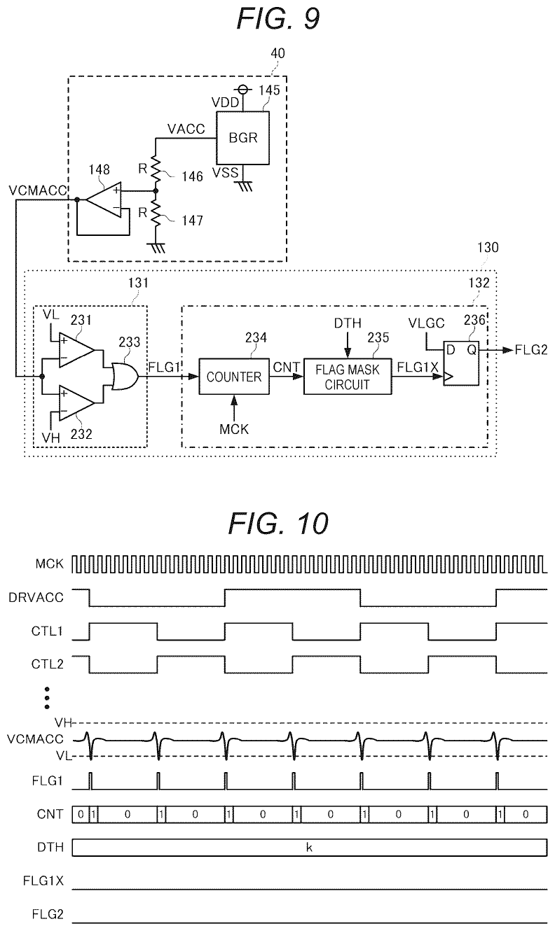

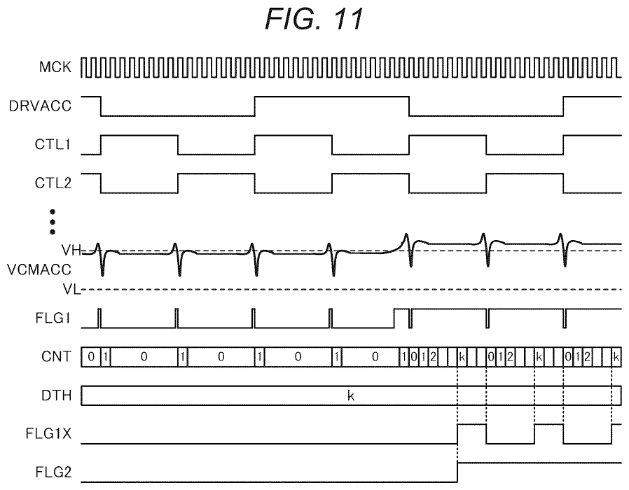

FIG. 2 is a diagram showing a configuration example of the selection circuit 50 and the analog-digital conversion circuit 60. In the example of FIG. 2, the selection circuit 50 includes ten low-pass filters 51p, 51n, 52p, 52n, 53p, 53n, 54p, 54n, 55p, and 55n and a multiplexer 56.

Differential signals GRO1_P and GRO1_N constituting the angular velocity detection signal GRO1 are low-pass filtered by the low-pass filters 51p and 51n, respectively, and input to the multiplexer 56.

Differential signals GRO2_P and GRO2_N constituting the vibration leakage signal GRO2 are low-pass filtered by the low-pass filters 52p and 52n, respectively, and input to the multiplexer 56.

Differential signals AXO_P and AXO_N constituting the X-axis acceleration detection signal AXO are low-pass filtered by the low-pass filters 53p and 53n, respectively, and input to the multiplexer 56.

Differential signals AYO_P and AYO_N constituting the Y-axis acceleration detection signal AYO are low-pass filtered by the low-pass filters 54p and 54n, respectively, and input to the multiplexer 56.

Differential signals TSO_P and TSO_N constituting the temperature detection signal TSO are low-pass filtered by the low-pass filters 55p and 55n, respectively, and input to the multiplexer 56.

The multiplexer 56 selects, according to the selection signal SEL, differential signals from among the low-pass filtered differential signals GRO1_P and GRO1_N, the low-pass filtered differential signals GRO2_P and GRO2_N, the low-pass filtered differential signals AXO_P and AXO_N, the low-pass filtered differential signals AYO_P and AYO_N, and the low-pass filtered differential signals TSO_P and TSO_N, and outputs the differential signals as differential signals MXO_P and MXO_N.

In the example of FIG. 2, the analog-digital conversion circuit 60 includes a pre-charge circuit 61, a programmable gain amplifier 62, a successive approximation register (SAR) type analog-digital converter 63, and an SAR control circuit 64.

The pre-charge circuit 61 assists charging based on the differential signals MXO_P and MXO_N by charging an input node of the programmable gain amplifier 62 before conversion processing of the successive approximation register type analog-digital converter 63 is started according to the control signal supplied from the control circuit 90.

The programmable gain amplifier 62 outputs differential signals PO_P and PO_N obtained by amplifying the differential signals MXO_P and MXO_N. A gain of the programmable gain amplifier 62 is variably set according to the type of the differential signals selected as the differential signals MXO_P and MXO_N according to the control signal supplied from the control circuit 90.

The successive approximation register type analog-digital converter 63 converts a voltage difference between the differential signals PO_P and PO_N into the digital signal ADO using the voltage difference between the full scale voltage VFSAD and the ground voltage VSS as a full scale, and outputs the digital signal ADO.

The SAR control circuit 64 operates according to the clock signal MCK, and performs processing of selecting a reference voltage for comparison according to a comparison result and a timing of successive approximation performed by the successive approximation register type analog-digital converter 63.

### 1-3. Channel Configuration of Time Division Processing

As described above, the analog-digital conversion circuit 60 converts the differential signal selected by the selection circuit 50 based on the selection signal SEL into the digital signal ADO, and outputs the digital signal ADO. That is, the analog-digital conversion circuit 60 processes the angular velocity detection signal GRO1, the vibration leakage signal GRO2, the X-axis acceleration detection signal AXO, the Y-axis acceleration detection signal AYO, and the temperature detection signal TSO in a time division manner, and converts the signals into digital signals.

FIG. 3 is a diagram showing an example of a channel configuration of time division processing performed by the analog-digital conversion circuit 60.

As shown in FIG. 3, in a first channel, the 3-bit selection signal SEL is “000”, and the angular velocity detection signal GRO1 is selected by the selection circuit 50 as an input signal of the analog-digital conversion circuit 60. Accordingly, the analog-digital conversion circuit 60 converts a voltage difference between the angular velocity detection signal GRO1, specifically, the differential signals GRO1_P and GRO1_N, into the digital signal ADO in a period of the first channel. As described above, in the first channel, processing for the angular velocity detection signal GRO1 is performed.

In a second channel following the first channel, the 3-bit selection signal SEL is “001”, and the vibration leakage signal GRO2 is selected by the selection circuit 50 as an input signal of the analog-digital conversion circuit 60. Accordingly, the analog-digital conversion circuit 60 converts a voltage difference between the vibration leakage signal GRO2, specifically, the differential signals GRO2_P and GRO2_N, into the digital signal ADO in a period of the second channel. As described above, in the second channel, processing for the vibration leakage signal GRO2 is performed.

In a third channel following the second channel, the 3-bit selection signal SEL is “010”, and the X-axis acceleration detection signal AXO is selected by the selection circuit 50 as an input signal of the analog-digital conversion circuit 60. Accordingly, the analog-digital conversion circuit 60 converts a voltage difference between the X-axis acceleration detection signal AXO, specifically, the differential signals AXO_P and AXO_N, into the digital signal ADO in a period of the third channel. As described above, in the third channel, processing for the X-axis acceleration detection signal AXO is performed.

In a fourth channel following the third channel, the 3-bit selection signal SEL is “011”, and the Y-axis acceleration detection signal AYO is selected by the selection circuit 50 as an input signal of the analog-digital conversion circuit 60. Accordingly, the analog-digital conversion circuit 60 converts a voltage difference between the Y-axis acceleration detection signal AYO, specifically, the differential signals AYO_P and AYO_N, into the digital signal ADO in a period of the fourth channel. As described above, in the fourth channel, processing for the Y-axis acceleration detection signal AYO is performed.

In a fifth channel following the fourth channel, the 3-bit selection signal SEL is “100”, and the temperature detection signal TSO is selected by the selection circuit 50 as an input signal of the analog-digital conversion circuit 60. Accordingly, the analog-digital conversion circuit 60 converts a voltage difference between the temperature detection TSO, specifically, the signal differential signals TSO_P and TSO_N, into the digital signal ADO in a period of the fifth channel. As described above, in the fifth channel, processing for the temperature detection signal TSO is performed.

The fifth channel is returned to the first channel. That is, a plurality of periods of the first channel to the fifth channel are repeated in order. In the digital signal processing circuit 70, an order and a coefficient value of a digital filter, a type and a coefficient value of correction operation, and the like are changed for each channel according to a signal to be processed.

### 1-4. Configuration of Failure Diagnosis Circuit

FIG. 4 is a diagram showing a configuration example of a part of the reference voltage generation circuit 40 and the failure diagnosis circuit 80. In the example of FIG. 4, the reference voltage generation circuit 40 includes a bandgap reference circuit 141, resistors 142 and 143, and an operational amplifier 144.

The bandgap reference circuit 141 is a circuit that generates a constant full scale voltage VFSAD that is stable with respect to fluctuation in the temperature and the power supply voltage VDD by using a bandgap voltage of a semiconductor element. Since a configuration of the bandgap reference circuit is well known, illustration and description thereof are omitted.

The resistors 142 and 143 have the same resistance value R, and a voltage obtained by dividing the full scale voltage VFSAD by half by the resistors 142 and 143 is supplied to a non-inverting input terminal of the operational amplifier 144.

An inverting input terminal of the operational amplifier 144 is coupled to an output terminal of the operational amplifier 144, and the operational amplifier 144 functions as a voltage follower. Accordingly, the output terminal of the operational amplifier 144 is ½ of the full scale voltage VFSAD, and this voltage is output from the reference voltage generation circuit 40 as the common voltage VCMAD.

The failure diagnosis circuit 80 includes comparators 181 and 182, an OR circuit 183, a counter 184, a flag mask circuit 185, and a D-type flip-flop 186.

The common voltage VCMAD is supplied to an inverting input terminal of the comparator 181, and a predetermined threshold voltage VL is supplied to a non-inverting input terminal of the comparator 181. An output terminal of the comparator 181 is at a low level when the common voltage VCMAD is equal to or higher than the threshold voltage VL, and is at a high level when the common voltage VCMAD is lower than the threshold voltage VL.

The common voltage VCMAD is supplied to a non-inverting input terminal of the comparator 182, and a predetermined threshold voltage VH higher than the threshold voltage VL is supplied to an inverting input terminal of the comparator 182. An output terminal of the comparator 182 is at a low level when the common voltage VCMAD is equal to or lower than the threshold voltage VH, and is at a high level when the common voltage VCMAD is higher than the threshold voltage VH.

The OR circuit 183 receives an output signal of the comparator 181 and an output signal of the comparator 182, and outputs an OR signal of these signals. That is, the output signal of the OR circuit 183 is at a low level when both the output signal of the comparator 181 and the output signal of the comparator 182 are at a low level, and is at a high level when at least one of the output signal of the comparator 181 and the output signal of the comparator 182 is at a high level.

Accordingly, the output signal of the OR circuit 183 is at a low level when the common voltage VCMAD is equal to or higher than the threshold voltage VL and equal to or lower than the threshold voltage VH, and is at a high level when the common voltage VCMAD is lower than the threshold voltage VL or higher than the threshold voltage VH. The comparators 181 and 182 and the OR circuit 183 constitute the abnormality determination circuit 81, and the output signal of the OR circuit 183 becomes the abnormality determination signal FLG1. That is, the abnormality determination circuit 81 determines that the common voltage VCMAD is normal when the common voltage VCMAD is equal to or higher than the threshold voltage VL and equal to or lower than the threshold voltage VH, determines that the common voltage VCMAD is abnormal when the common voltage VCMAD is lower than the threshold voltage VL or higher than the threshold voltage VH, and outputs the abnormality determination signal FLG1 indicating the determination result.

The threshold voltages VL and VH may be fixed values or may be variably set in the storage unit 100.

The counter 184 resets a count value CNT to 0 when the abnormality determination signal FLG1 is at a low level, and increases the count value CNT by 1 when the abnormality determination signal FLG1 is at a high level, at a timing of a rising edge of the clock signal MCK. That is, the counter 184 measures a time during which the abnormality determination signal FLG1 continues to be at the high level in a cycle of the clock signal MCK, and outputs the count value CNT indicating a measurement result.

The flag mask circuit 185 compares the count value CNT with a threshold DTH, and outputs a flag signal FLG1X indicating a comparison result. Specifically, the flag mask circuit 185 outputs a low-level flag signal FLG1X when the count value CNT is lower than the threshold DTH, and outputs a high-level flag signal FLG1X when the count value CNT is equal to or higher than the threshold DTH.

As described above, even when the reference voltage generation circuit 40 does not fail, the abnormality determination circuit 81 may temporarily output the abnormality determination signal FLG1 indicating that the common voltage VCMAD is abnormal. Accordingly, a threshold TH is set to a value larger than a value obtained by dividing a maximum time, during which the common voltage VCMAD may temporarily become abnormal, by the cycle of the clock signal MCK. The threshold DTH may be a fixed value or may be variably set in the storage unit 100.

In the D-type flip-flop 186, the power supply voltage VLGC is input to a data input terminal D, and the flag signal FLG1X is input to a clock input terminal. The D-type flip-flop 186 takes in the power supply voltage VLGC and outputs a high-level failure diagnosis signal FLG2 at a timing of a rising edge of the flag signal FLG1X.

The D-type flip-flop 186 outputs a low-level failure diagnosis signal FLG2 in an initial state after the power is turned on. Then, once the failure diagnosis signal FLG2 becomes at the high level, the failure diagnosis signal FLG2 continues to maintain the high level. Accordingly, the external device reads the failure diagnosis signal FLG2, and can determine that the reference voltage generation circuit 40 fails when the failure diagnosis signal FLG2 is at the high level, and that the reference voltage generation circuit 40 does not fail when the failure diagnosis signal FLG2 is at the low level.

In the example of FIG. 4, the common voltage VCMAD is a voltage obtained by dividing the full scale voltage VFSAD by half by the resistors 142 and 143. Therefore, when the full scale voltage VFSAD is always abnormal, the common voltage VCMAD is also always abnormal, and the abnormality determination signal FLG1 is always at the high level. Accordingly, when the operational amplifier 144 fails and the common voltage VCMAD is always abnormal, and when the bandgap reference circuit 141 fails and the full scale voltage VFSAD is always abnormal, the failure diagnosis signal FLG2 is at the high level, and the failure diagnosis circuit 80 can diagnose that the reference voltage generation circuit 40 fails.

FIG. 5 is a diagram showing an example of waveforms of various signals including the common voltage VCMAD, the abnormality determination signal FLG1, and the failure diagnosis signal FLG2 when the reference voltage generation circuit 40 does not fail. FIG. 6 is a diagram showing an example of waveforms of various signals including the common voltage VCMAD, the abnormality determination signal FLG1, and the failure diagnosis signal FLG2 when the reference voltage generation circuit 40 fails.

In the examples of FIGS. 5 and 6, a state signal CONV is at a low level in a sampling period during which the analog-digital conversion circuit 60 samples a voltage of the output signal MXO of the selection circuit 50, and the state signal CONV is at a high level in a conversion period during which the analog-digital conversion circuit 60 holds the sampled voltage and converts the sampled voltage into the digital signal ADO. As shown in FIGS. 5 and 6, the analog-digital conversion circuit 60 alternately repeats the sampling period and the conversion period in synchronization with the repetition of the first channel to the fifth channel. In FIGS. 1 and 2, the state signal CONV is not shown.

In the embodiment, in order to reduce an area of the reference voltage generation circuit 40, a supply capability of the full scale voltage VFSAD to the analog-digital conversion circuit 60 is not necessarily sufficient. Therefore, at switching between the sampling period and the conversion period of the analog-digital conversion circuit 60, the full scale voltage VFSAD greatly fluctuates, and accordingly, as shown in FIGS. 5 and 6, the common voltage VCMAD also greatly fluctuates. A timing of switching from the conversion period to the sampling period is a timing at which the analog-digital conversion circuit 60 starts the sampling of the output signal MXO of the selection circuit 50. A timing of switching from the sampling period to the conversion period is a timing at which the analog-digital conversion circuit 60 ends the sampling of the output signal MXO of the selection circuit 50.

In the example of FIG. 5, the common voltage VCMAD is lower than the threshold voltage VL at the timing at which the sampling period and the conversion period which periodically arrive are switched. As a result, a phenomenon in which the abnormality determination signal FLG1 is at the high level for a period of one cycle of the clock signal MCK is periodically repeated. Even when the common voltage VCMAD is temporarily lower than the threshold voltage VL at the timing at which the sampling period and the conversion period are switched, the operation of the analog-digital conversion circuit 60 is not affected, so that the reference voltage generation circuit 40 does not fail. However, if the common voltage VCMAD temporarily fluctuates and the failure diagnosis signal output circuit 82 takes in the abnormality determination signal FLG1 at the timing at which the abnormality determination signal FLG1 is temporarily at the high level, the high-level failure diagnosis signal FLG2 is output. When the external device reads the high-level failure diagnosis signal FLG2 via the interface circuit 110, the external device erroneously determines that the reference voltage generation circuit 40 fails.

In the example of FIG. 6, the reference voltage generation circuit 40 fails, and the common voltage VCMAD is higher than the threshold voltage VH. Actually, as in the example of FIG. 5, since the common voltage VCMAD greatly fluctuates in the switching between the sampling period and the conversion period of the analog-digital conversion circuit 60, the common voltage VCMAD temporarily falls within a range from equal to or high than the threshold voltage VL to equal to or lower than the threshold voltage VH. Therefore, in the example of FIG. 6, contrary to the example of FIG. 5, the abnormality determination signal FLG1 is temporarily at the low level at the timing at which the sampling period and the conversion period are switched. Accordingly, if the failure diagnosis signal output circuit 82 takes in the abnormality determination signal FLG1 at the timing at which the abnormality determination signal FLG1 is temporarily at the low level, the low-level failure diagnosis signal FLG2 is output. When the external device reads the low-level failure diagnosis signal FLG2 via the interface circuit 110, the external device erroneously determines that the reference voltage generation circuit 40 does not fail.

On the other hand, in the embodiment, when the abnormality determination signal FLG1 is at the high level continuously for a predetermined time, the failure diagnosis signal output circuit 82 diagnoses that the reference voltage generation circuit 40 fails, and outputs the high-level failure diagnosis signal FLG2.

Therefore, in the example of FIG. 5, even when the abnormality determination signal FLG1 is temporarily at the high level, the failure diagnosis signal FLG2 continues to maintain the low level. Accordingly, even when the external device reads the failure diagnosis signal FLG2 via the interface circuit 110 at any timing, the external device can correctly determine that the reference voltage generation circuit 40 does not fail.

In the example of FIG. 6, after the failure diagnosis signal FLG2 first becomes at the high level, even when the determination is abnormality signal FLG1 temporarily at the low level, the failure diagnosis signal FLG2 continues to maintain the high level. Accordingly, even when the external device reads the failure diagnosis signal FLG2 via the interface circuit 110 at any timing, the external device can correctly determine that the reference voltage generation circuit 40 fails.

### 1-5. Processing Procedure of Failure Diagnosis Circuit

FIG. 7 is a flowchart showing an example of a processing procedure of the failure diagnosis circuit 80. In the flowchart of FIG. 7, processing of respective steps may be appropriately exchanged.

As shown in FIG. 7, first, in step S1, the failure diagnosis signal output circuit 82 of the failure diagnosis circuit 80 sets the failure diagnosis signal FLG2 to have no failure. Specifically, the failure diagnosis signal output circuit 82 sets the failure diagnosis signal FLG2 to a low level.

Next, in step S2, the abnormality determination circuit 81 of the failure diagnosis circuit 80 determines whether the common voltage VCMAD is within a predetermined range. In step S2, when the common voltage VCMAD is within the predetermined range, that is, when the common voltage VCMAD is equal to or higher than the threshold voltage VL and equal to or lower than the threshold voltage VH, in step S3, the abnormality determination circuit 81 sets the abnormality determination signal FLG1 to have no abnormality. Specifically, the abnormality determination circuit 81 sets the abnormality determination signal FLG1 to a low level.

On the other hand, in step S2, when the common voltage VCMAD is not within the predetermined range, that is, when the common voltage VCMAD is lower than the threshold voltage VL or higher than the threshold voltage VH, in step S4, the abnormality determination circuit 81 sets the abnormality determination signal FLG1 to have an abnormality. Specifically, the abnormality determination circuit 81 sets the abnormality determination signal FLG1 to a high level.

Next, when the common voltage VCMAD returns to the predetermined range in step S6 before a predetermined time elapses in step S5, the abnormality determination circuit 81 sets the abnormality determination signal FLG1 to have no abnormality in step S3. Then, the failure diagnosis circuit 80 performs the processing after step S1 again.

On the other hand, when the common voltage VCMAD does not return to the predetermined range in step S6 before the predetermined time elapses in step S5, the failure diagnosis signal output circuit 82 sets the failure diagnosis signal FLG2 to have a failure in step S7. Specifically, the failure diagnosis signal output circuit 82 sets the failure diagnosis signal FLG2 to a high level.

### 1-6. Operation and Effect

In the physical quantity sensor 1 according to the first embodiment described above, the physical quantity detection circuit 2 includes the failure diagnosis circuit 80 that monitors the common voltage VCMAD generated by the reference voltage generation circuit 40 and supplied to the analog-digital conversion circuit 60, performs the failure diagnosis for the reference voltage generation circuit 40, and outputs the failure diagnosis signal FLG2 indicating a result of the failure diagnosis. When a state in which the common voltage VCMAD is not within the predetermined range continues for a predetermined time, the failure diagnosis circuit 80 diagnoses that the reference voltage generation circuit 40 fails. When the common voltage VCMAD temporarily fluctuates according to the operation of the analog-digital conversion circuit 60 and is not within the predetermined range, the failure diagnosis circuit 80 diagnoses that the reference voltage generation circuit 40 does not fail unless the state continues for the predetermined time. Accordingly, according to the physical quantity sensor 1 according to the first embodiment, even when the common voltage VCMAD temporarily fluctuates, the failure diagnosis circuit 80 can reduce the possibility of erroneously diagnosing that the reference voltage generation circuit 40 fails. In particular, even when the common voltage VCMAD temporarily fluctuates at the timing at which the analog-digital conversion circuit 60 starts sampling of the signal MXO which is an analog signal or at the timing at which the analog-digital conversion circuit 60 ends the sampling, the failure diagnosis circuit 80 can reduce the possibility of erroneously determining that the reference voltage generation circuit 40 fails. For example, even when the supply capability of the common voltage VCMAD by the reference voltage generation circuit 40 is relatively low, since the possibility of erroneous determination by the failure diagnosis circuit 80 is reduced, a size of the reference voltage generation circuit 40 can be reduced, which is advantageous for cost reduction.

Specifically, the failure diagnosis circuit 80 includes the abnormality determination circuit 81 that determines whether the common voltage VCMAD is abnormal and outputs the abnormality determination signal FLG1 indicating the determination result, and the failure diagnosis signal output circuit 82 that diagnoses whether the reference voltage generation circuit 40 fails based on the abnormality determination signal FLG1 and outputs the failure diagnosis signal FLG2 indicating the diagnosis result. When the abnormality determination signal FLG1 continues for a predetermined time and the common voltage VCMAD is abnormal, the failure diagnosis signal output circuit 82 diagnoses that the reference voltage generation circuit 40 fails. Accordingly, when the common voltage temporarily fluctuates, even if the abnormality VCMAD determination circuit 81 temporarily outputs the abnormality determination signal FLG1 indicating that the common voltage VCMAD is abnormal, it is possible to reduce the possibility that the failure diagnosis signal output circuit 82 erroneously outputs the failure diagnosis signal FLG2 indicating that the reference voltage generation circuit 40 fails.

In the physical quantity sensor 1 according to the first embodiment, when the reference voltage generation circuit 40 fails, the failure diagnosis signal output circuit 82 can promptly output the failure diagnosis signal FLG2 indicating that the reference voltage generation circuit 40 fails. Therefore, for example, it is possible to satisfy a request for a short FTTI in an upper system. The FTTI is an abbreviation of fault tolerant time interval, and is a time from occurrence of an abnormality in the system to the transition to a safe state.

As described above, according to the embodiment, it is possible to reduce the possibility that the failure diagnosis circuit 80 erroneously determines that the reference voltage generation circuit 40 fails, and thus it is possible to improve the reliability of the physical quantity sensor 1.

### 2. Second Embodiment

Hereinafter, regarding a physical quantity sensor according to a second embodiment, the same components as those of the first embodiment are denoted by the same reference signs, the description of the contents overlapping with those of the first embodiment will be omitted or simplified, and the contents different from those of the first embodiment will be mainly described.

### 2-1. Configuration of Physical Quantity Sensor

FIG. 8 is a functional block diagram of the physical quantity sensor according to the second embodiment. Similarly to the first embodiment, the physical quantity sensor 1 according to the second embodiment includes the physical quantity detection circuit 2, the angular velocity detection element 3, the acceleration detection element 4X, and the acceleration detection element 4Y.

Since the functions of the angular velocity detection element 3, the acceleration detection element 4X, and the acceleration detection element 4Y are the same as those in the first embodiment, the description thereof is omitted.

Similarly to the first embodiment, the physical quantity detection circuit 2 includes the angular velocity signal processing circuit 10, the acceleration signal processing circuit 20, the temperature sensor 30, the reference voltage generation circuit 40, the selection circuit 50, the analog-digital conversion circuit 60, the digital signal processing circuit 70, the control circuit 90, the storage unit 100, the interface circuit 110, the oscillation circuit 120, and a failure diagnosis circuit 130, and may be implemented by, for example, a one-chip integrated circuit. The physical quantity detection circuit 2 may have a configuration obtained by omitting or changing some of the elements, or adding other elements.

The functions of the angular velocity signal processing circuit 10, the acceleration signal processing circuit 20, the temperature sensor 30, the reference voltage generation circuit 40, the selection circuit 50, the analog-digital conversion circuit 60, the digital signal processing circuit 70, the control circuit 90, the storage unit 100, the interface circuit 110, and the oscillation circuit 120 are the same as those in the first embodiment, and thus the description thereof is omitted.

The failure diagnosis circuit 130 performs failure diagnosis for the reference voltage generation circuit 40. Specifically, the failure diagnosis circuit 130 monitors the common voltage VCMACC which is the reference voltage supplied from the reference voltage generation circuit 40 to the acceleration signal processing circuit 20 which is one of the physical quantity signal processing circuits, and diagnoses that the reference voltage generation circuit 40 fails when a state in which the common voltage VCMACC is not within a predetermined range continues for a predetermined time. The acceleration signal processing circuit 20 is an example of a “first circuit”.

In the embodiment, the failure diagnosis circuit 130 includes an abnormality determination circuit 131 and a failure diagnosis signal output circuit 132.

The abnormality determination circuit 131 diagnoses whether the reference voltage generation circuit 40 fails based on the abnormality determination signal FLG1, and outputs the failure diagnosis signal FLG2 indicating a diagnosis result. The abnormality determination circuit 131 determines whether the common voltage VCMACC is abnormal, and outputs the abnormality determination signal FLG1 indicating a determination result. For example, the abnormality determination signal FLG1 may be a flag signal that is at a high level when the common voltage VCMACC is abnormal and is at a low level when the common voltage VCMACC is normal.

The failure diagnosis signal output circuit 132 diagnoses whether the reference voltage generation circuit 40 fails based on the abnormality determination signal FLG1, and outputs the failure diagnosis signal FLG2 indicating a diagnosis result. In the embodiment, the common voltage VCMACC temporarily fluctuates in at least one timing of a rising edge and a falling edge of the drive signal DRVACC for driving the acceleration detection elements 4X and 4Y.

In at least one timing of the rising edges and the falling edges of the control signals CTL1 to CTLn for controlling the acceleration signal processing circuit 20, the common voltage VCMACC temporarily fluctuates. Therefore, even when the reference voltage generation circuit 40 does not fail, the abnormality determination circuit 131 may temporarily output the abnormality determination signal FLG1 indicating that the common voltage VCMACC is abnormal. Therefore, in order not to erroneously determine that the reference voltage generation circuit 40 fails, the failure diagnosis signal output circuit 132 diagnoses that the reference voltage generation circuit 40 fails when the abnormality determination signal FLG1 continues for a predetermined time and the common voltage VCMACC is abnormal. For example, the failure diagnosis signal FLG2 may be a flag signal that is at a high level when the reference voltage generation circuit 40 fails and is at a low level when the reference voltage generation circuit 40 does not fail.

### 2-2. Configuration of Failure Diagnosis Circuit

FIG. 9 is a diagram showing a configuration example of a part of the reference voltage generation circuit 40 and the failure diagnosis circuit 130. In the example of FIG. 9, the reference voltage generation circuit 40 includes a bandgap reference circuit 145, resistors 146 and 147, and an operational amplifier 148.

The bandgap reference circuit 145 is a circuit that generates a constant power supply voltage VACC that is stable with respect to a variation in the temperature or the power supply voltage VDD by using a bandgap voltage of a semiconductor element. Since a configuration of the bandgap reference circuit is well known, illustration and description thereof are omitted.

The resistors 146 and 147 have the same resistance value R, and a voltage obtained by dividing the power supply voltage VACC by half by the resistors 146 and 147 is supplied to a non-inverting input terminal of the operational amplifier 148.

An inverting input terminal of the operational amplifier 148 is coupled to an output terminal of the operational amplifier 148, and the operational amplifier 148 functions as a voltage follower. Accordingly, the output terminal of the operational amplifier 148 is ½ of the power supply voltage VACC, and this voltage is output from the reference voltage generation circuit 40 as the common voltage VCMACC.

The failure diagnosis circuit 130 includes comparators 231 and 232, an OR circuit 233, a counter 234, a flag mask circuit 235, and a D-type flip-flop 236.

The common voltage VCMACC is supplied to an inverting input terminal of the comparator 231, and a predetermined threshold voltage VL is supplied to a non-inverting input terminal of the comparator 231. An output terminal of the comparator 231 is at a low level when the common voltage VCMACC is equal to or higher than the threshold voltage VL, and is at a high level when the common voltage VCMACC is lower than the threshold voltage VL.

The common voltage VCMACC is supplied to a non-inverting input terminal of the comparator 232, and the predetermined threshold voltage VH higher than the threshold voltage VL is supplied to an inverting input terminal of the comparator 232. An output terminal of the comparator 232 is at a low level when the common voltage VCMACC is equal to or lower than the threshold voltage VH, and is at a high level when the common voltage VCMACC is higher than the threshold voltage VH.

The OR circuit 233 receives an output signal of the comparator 231 and an output signal of the comparator 232, and outputs an OR signal of these signals. That is, the output signal of the OR circuit 233 is at a low level when both the output signal of the comparator 231 and the output signal of the comparator 232 are at a low level, and is at a high level when at least one of the output signal of the comparator 231 and the output signal of the comparator 232 is at a high level.

Accordingly, the output signal of the OR circuit 233 is at a low level when the common voltage VCMAD is equal to or higher than the threshold voltage VL and equal to or lower than the threshold voltage VH, and is at a high level when the common voltage VCMAD is lower than the threshold voltage VL or higher than the threshold voltage VH. The comparators 231 and 232 and the OR circuit 233 constitute the abnormality determination circuit 131, and the output signal of the OR circuit 233 becomes the abnormality determination signal FLG1. That is, the abnormality determination circuit 131 determines that the common voltage VCMACC is normal when the common voltage VCMACC is equal to or higher than the threshold voltage VL and equal to or lower than the threshold voltage VH, determines that the common voltage VCMACC is abnormal when the common voltage VCMACC is lower than the threshold voltage VL or higher than the threshold voltage VH, and outputs the abnormality determination signal FLG1 indicating the determination result.

The threshold voltages VL and VH may be fixed values or may be variably set in the storage unit 100.

The counter 234 resets the count value CNT to 0 when the abnormality determination signal FLG1 is at a low level, and increases the count value CNT by 1 when the abnormality determination signal FLG1 is at a high level, at a timing of a rising edge of the clock signal MCK. That is, the counter 234 measures a time during which the abnormality determination signal FLG1 continues to be at the high level in a cycle of the clock signal MCK, and outputs the count value CNT indicating a measurement result.

The flag mask circuit 235 compares the count value CNT with the threshold DTH, and outputs the flag signal FLG1X indicating a comparison result. Specifically, the flag mask circuit 235 outputs a low-level flag signal FLG1X when the count value CNT is lower than the threshold DTH, and outputs a high-level flag signal FLG1X when the count value CNT is equal to or higher than the threshold DTH.

As described above, even when the reference voltage generation circuit 40 does not fail, the abnormality determination circuit 131 may temporarily output the abnormality determination signal FLG1 indicating that the common voltage VCMACC is abnormal. Accordingly, the threshold TH is set to a value larger than a value obtained by dividing a maximum time, during which the common voltage VCMACC may temporarily become abnormal, by the cycle of the clock signal MCK. The threshold DTH may be a fixed value or may be variably set in the storage unit 100.

In the D-type flip-flop 236, the power supply voltage VLGC is input to the data input terminal D, and the flag signal FLG1X is input to a clock input terminal. The D-type flip-flop 236 takes in the power supply voltage VLGC and outputs the failure diagnosis signal FLG2 at a timing of a rising edge of the flag signal FLG1X.

The D-type flip-flop 236 outputs a low-level failure diagnosis signal FLG2 in an initial state after the power is turned on. Then, once the failure diagnosis signal FLG2 becomes at the high level, the failure diagnosis signal FLG2 continues to maintain the high level. Accordingly, the external device reads the failure diagnosis signal FLG2, and can determine that the reference voltage generation circuit 40 fails when the failure diagnosis signal FLG2 is at the high level, and that the reference voltage generation circuit 40 does not fail when the failure diagnosis signal FLG2 is at the low level.

In the example of FIG. 9, the common voltage VCMACC is a voltage obtained by dividing the power supply voltage VACC by half by the resistors 146 and 147. Therefore, when the power supply voltage VACC is always abnormal, the common voltage VCMACC is also always abnormal, and the abnormality determination signal FLG1 is always at the high level. Accordingly, when the operational amplifier 148 fails and the common voltage VCMACC is always abnormal, and when the bandgap reference circuit 145 fails and the power supply voltage VACC is a abnormal, the failure diagnosis signal FLG2 is at the high level, and the failure diagnosis circuit 130 can diagnose that the reference voltage generation circuit 40 fails.

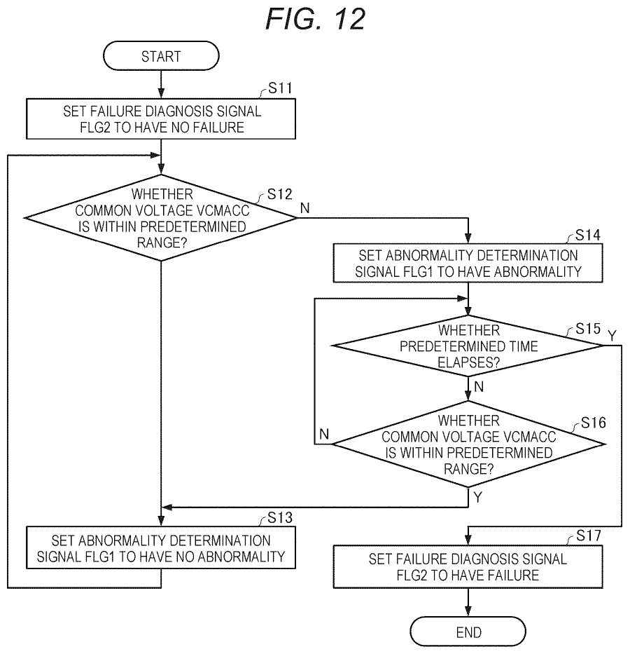

FIG. 10 is a diagram showing an example of waveforms of various signals including the common voltage VCMACC, the abnormality determination signal FLG1, and the failure diagnosis signal FLG2 when the reference voltage generation circuit 40 does not fail. FIG. 11 is a diagram showing an example of waveforms of various signals including the common voltage VCMACC, the abnormality determination signal FLG1, and the failure diagnosis signal FLG2 when the reference voltage generation circuit 40 fails.

In the embodiment, in order to reduce the area of the reference voltage generation circuit 40, a supply capability of the power supply voltage VACC to the acceleration signal processing circuit 20 is not necessarily sufficient. Since the high level of the drive signal DRVACC is the power supply voltage VACC, the power supply voltage VACC greatly fluctuates at the timings of the rising edge and the falling edge of the drive signal DRVACC, and accordingly, as shown in FIGS. 10 and 11, the common voltage VCMACC also greatly fluctuates. Similarly, since the high level of the control signals CTL1 to CTLn is the power supply voltage VACC, the power supply voltage VACC greatly fluctuates at the timings of the rising edge and the falling edge of each of the control signals CTL1 to CTLn, and accordingly, as shown in FIGS. 10 and 11, the common voltage VCMACC also greatly fluctuates.

In the example of FIG. 10, at the timings of the rising edge and the falling edge of the drive signal DRVACC and the timings of the rising edge and the falling edge of each of the control signals CTL1 to CTLn, the common voltage VCMACC is lower than the threshold voltage VL. As a result, a phenomenon in which the abnormality determination signal FLG1 is at the high level for a period of one cycle of the clock signal MCK is periodically repeated. Even when the common voltage VCMACC is temporarily lower than the threshold voltage VL at the timings of these edges, the operation of the acceleration signal processing circuit 20 is not affected, and thus the reference voltage generation circuit 40 does not fail. However, if the common voltage VCMACC temporarily fluctuates and the failure diagnosis signal output circuit 132 takes in the abnormality determination signal FLG1 at the timing at which the abnormality determination signal FLG1 is temporarily at the high level, the high-level failure diagnosis signal FLG2 is output. When the external device reads the high-level failure diagnosis signal FLG2 via the interface circuit 110, the external e erroneously determines that the reference voltage generation circuit 40 fails.

In the example of FIG. 11, the reference voltage generation circuit 40 fails, and the common voltage VCMACC is higher than the threshold voltage VH. Actually, as in the example of FIG. 10, since the common voltage VCMACC greatly fluctuates at the timings of the rising edge and the falling edge of the drive signal DRVACC and at the timings of the rising edge and the falling edge of each of the control signals CTL1 to CTLn, the common voltage VCMACC temporarily falls within the range of the threshold voltage VL or higher and the threshold voltage VH or lower. Therefore, in the example of FIG. 11, contrary to the example of FIG. 10, the abnormality determination signal FLG1 is temporarily at the low level at the timings of the edges. Accordingly, if the failure diagnosis signal output circuit 132 takes in the abnormality determination signal FLG1 at the timing at which the abnormality determination signal FLG1 is temporarily at the low level, the low-level failure diagnosis signal FLG2 is output. When the external device reads the low-level failure diagnosis signal FLG2 via the interface circuit 110, the external device erroneously determines that the reference voltage generation circuit 40 does not fail.

On the other hand, in the embodiment, when the abnormality determination signal FLG1 is at the high level continuously for a predetermined time, the failure diagnosis signal output circuit 132 diagnoses that the reference voltage generation circuit 40 fails, and outputs the high-level failure diagnosis signal FLG2.

Therefore, in the example of FIG. 10, in the failure diagnosis signal output circuit 132, even when the abnormality determination signal FLG1 is temporarily at the high level, the failure diagnosis signal FLG2 continues to maintain the low level. Accordingly, even when the external device reads the failure diagnosis signal FLG2 via the interface circuit 110 at any timing, the external device can correctly determine that the reference voltage generation circuit 40 does not fail.

In the example of FIG. 11, after the failure diagnosis signal FLG2 first becomes at the high level, even when the abnormality signal FLG1 is determination temporarily at the low level, the failure diagnosis signal FLG2 continues to maintain the high level. Accordingly, even when the external device reads the failure diagnosis signal FLG2 via the interface circuit 110 at any timing, the external device can correctly determine that the reference voltage generation circuit 40 fails.

### 2-3. Processing Procedure of Failure Diagnosis Circuit

FIG. 12 is a flowchart showing an example of a processing procedure of the failure diagnosis circuit 130. In the flowchart of FIG. 12, processing of respective steps may be appropriately exchanged.

As shown in FIG. 12, first, in step S11, the failure diagnosis signal output circuit 132 of the failure diagnosis circuit 130 sets the failure diagnosis signal FLG2 to have no failure. Specifically, the failure diagnosis signal output circuit 132 sets the failure diagnosis signal FLG2 to a low level.

Next, in step S12, the abnormality determination circuit 131 of the failure diagnosis circuit 130 determines whether the common voltage VCMACC is within a predetermined range. In step S12, when the common voltage VCMACC is within the predetermined range, that is, when the common voltage VCMACC is equal to or higher than the threshold voltage VL and equal to or lower than the threshold voltage VH, in step S13, the abnormality determination circuit 131 sets the abnormality determination signal FLG1 to have no abnormality. Specifically, the abnormality determination circuit 131 sets the abnormality determination signal FLG1 to a low level.

On the other hand, in step S12, when the common voltage VCMACC is not within the predetermined range, that is, when the common voltage VCMACC is lower than the threshold voltage VL or higher than the threshold voltage VH, in step S14, the abnormality determination circuit 131 sets the abnormality determination signal FLG1 to have an abnormality. Specifically, the abnormality determination circuit 131 sets the abnormality determination signal FLG1 to a high level.

Next, when the common voltage VCMACC returns to the predetermined range in step S16 before a predetermined time elapses in step S15, the abnormality determination circuit 131 sets the abnormality determination signal FLG1 to have no abnormality in step S13. Then, the failure diagnosis circuit 130 performs the processing after step S11 again.

On the other hand, when the common voltage VCMAD does not return to the predetermined range in step S16 before the predetermined time elapses in step S15, the failure diagnosis signal output circuit 132 sets the failure diagnosis signal FLG2 to have a failure in step S17. Specifically, the failure diagnosis signal output circuit 132 sets the failure diagnosis signal FLG2 to a high level.

In the physical quantity sensor 1 according to the second embodiment described above, the physical quantity detection circuit 2 includes the failure diagnosis circuit 130 that monitors the common voltage VCMACC generated by the reference voltage generation circuit 40 and supplied to the acceleration signal processing circuit 20, performs the failure diagnosis for the reference voltage generation circuit 40, and outputs the failure diagnosis signal FLG2 indicating a result of the failure diagnosis. When a state in which the common voltage VCMACC is not within the predetermined range continues for a predetermined time, the failure diagnosis circuit 130 diagnoses that the reference voltage generation circuit 40 fails. When the common voltage VCMACC temporarily fluctuates according to the operation of the acceleration signal processing circuit 20 and is not within the predetermined range, the failure diagnosis circuit 130 diagnoses that the reference voltage generation circuit 40 does not fail unless the state continues for the predetermined time. Accordingly, according to the physical quantity sensor 1 according to the second embodiment, even when the common voltage VCMACC temporarily fluctuates, the failure diagnosis circuit 130 can reduce the possibility of erroneously diagnosing that the reference voltage generation circuit 40 fails. In particular, even when the common voltage VCMACC temporarily fluctuates at the rising edge and the falling edge of the drive signal DRVACC for driving the acceleration detection elements 4X and 4Y or at the rising edge and the falling edge of each of the control signals CTL1 to CTLn for controlling the acceleration signal processing circuit 20, the failure diagnosis circuit 130 can reduce the possibility of erroneously determining that the reference voltage generation circuit 40 fails. For example, even when the supply capability of the common voltage VCMACC by the reference voltage generation circuit 40 is relatively low, since the possibility of erroneous determination by the failure diagnosis circuit 130 is reduced, a size of the reference voltage generation circuit 40 can be reduced, which is advantageous for cost reduction.

Specifically, the failure diagnosis circuit 130 includes the abnormality determination circuit 131 that determines whether the common voltage VCMACC is abnormal and outputs the abnormality determination signal FLG1 indicating the determination result, and the failure diagnosis signal output circuit 132 that diagnoses whether the reference voltage generation circuit 40 fails based on the abnormality determination signal FLG1 and outputs the failure diagnosis signal FLG2 indicating the diagnosis result. When the abnormality determination signal FLG1 continues for a predetermined time and the common voltage VCMACC is abnormal, the failure diagnosis signal output circuit 132 diagnoses that the reference voltage generation circuit 40 fails. Accordingly, when the common voltage VCMACC temporarily fluctuates, even if the abnormality determination circuit 131 temporarily outputs the abnormality determination signal FLG1 indicating that the common voltage VCMACC is abnormal, it is possible to reduce the possibility that the failure diagnosis signal output circuit 132 erroneously outputs the failure diagnosis signal FLG2 indicating that the reference voltage generation circuit 40 fails.

In the physical quantity sensor 1 according to the first embodiment, when the reference voltage generation circuit 40 fails, the failure diagnosis signal output circuit 132 can promptly output the failure diagnosis signal FLG2 indicating that the reference voltage generation circuit 40 fails. Therefore, for example, it is possible to satisfy a request for a short FTTI in an upper system.

As described above, according to the embodiment, it is possible to reduce the possibility that the failure diagnosis circuit 130 erroneously determines that the reference voltage generation circuit 40 fails, and thus it is possible to improve the reliability of the physical quantity sensor 1.

### 3. Modifications

For example, in the first embodiment, the failure diagnosis circuit 80 monitors the common voltage VCMAD, and in the second embodiment, the failure diagnosis circuit 130 monitors the common voltage VCMACC, but the failure diagnosis circuit may monitor both the common voltage VCMAD and the common voltage VCMACC. That is, the physical quantity sensor 1 may have a configuration in which the first embodiment and the second embodiment are combined.

Although the failure diagnosis circuit 80 monitors the common voltage VCMAD in the first embodiment, the failure diagnosis circuit 80 may monitor the full scale voltage VFSAD or may monitor any voltage that fluctuates according to the fluctuation of the full scale voltage VFSAD. In the second embodiment, the failure diagnosis circuit 130 monitors the common voltage VCMACC, but may monitor the power supply voltage VACC, or may monitor any voltage that fluctuates according to the fluctuation of the power supply voltage VACC. Alternatively, the failure diagnosis circuit may monitor any voltage, such as the common voltage VCMGR, which fluctuates according to the fluctuation of the power supply voltage VGR, or may monitor the power supply voltage VGR.

In the above embodiments, the physical quantity sensor 1 detects both the angular velocity and the acceleration as the physical quantities, but may detect one of the angular velocity and the acceleration. The physical quantity sensor 1 may detect a physical quantity other than the angular velocity and the acceleration as the physical quantity.

In the above embodiments, the analog-digital conversion circuit 60 receives the differential signal and converts the differential signal into the digital signal ADO, but may receive a single-ended signal and convert the single-ended signal into the digital signal ADO.

In the above embodiments, the physical quantity sensor 1 includes the angular velocity detection element 3, the acceleration detection element 4X, and the acceleration detection element 4Y, but may be a sensor including only a part of these physical quantity detection elements. In the above embodiments, the angular velocity detection element is only the angular velocity detection element 3 that detects the angular velocity around the Z-axis, but one or both of the angular velocity detection element that detects the angular velocity around the X-axis and the angular velocity detection element that detects the angular velocity around the Y-axis may be further added, and the drive circuit and the detection circuit may be coupled to each of the angular velocity detection elements. In the above embodiments, the two acceleration detection elements of the acceleration detection element 4X that detects the acceleration in the X-axis direction and the acceleration detection element 4Y that detects the acceleration in the Y-axis direction are provided as the acceleration detection elements, but an acceleration detection element that detects the acceleration in the Z-axis direction may be further added, and the drive circuit and the detection circuit may be coupled to each of the acceleration detection elements. The physical quantity sensor 1 may include a physical quantity detection element that detects a physical quantity other than the angular velocity and the acceleration, for example, a physical quantity detection element that detects a physical quantity such as an angular acceleration, a velocity, and a force.

In the above embodiments, the example in which the vibrator element of the angular velocity detection element 3 is the double T-shaped quartz crystal vibrator element is described, but the vibrator element of the physical quantity detection element that detects various physical quantities may be, for example, a tuning fork type or a comb tooth type, or may be a tone piece type having a shape such as a triangular column, a square column, or a cylindrical shape. As a material of the vibrator element of the physical quantity detection element, for example, piezoelectric material such as piezoelectric single crystal such as lithium tantalate (LiTaO₃) or lithium niobate (LiNbO₃) or piezoelectric ceramics such as lead zirconate titanate (PZT) may be used instead of quartz crystal (SiO₂), or a silicon semiconductor may be used. The vibrator element of the physical quantity detection element may have, for example, a structure in which a piezoelectric thin film of zinc oxide (ZnO), aluminum nitride (AlN), and the like sandwiched between drive electrodes is disposed on a part of a surface of the silicon semiconductor.

In the above embodiments, the piezoelectric angular velocity detection element 3 and the electrostatic capacitance acceleration detection elements 4X and 4Y are exemplified, but the physical quantity detection element that detects various physical quantities is not limited to the piezoelectric type or the electrostatic capacitance type element, and may be an element of an electrodynamic type, an eddy current type, an optical type, a strain gauge type, and the like. A detection method of the physical quantity detection element is not limited to the vibration method, and may be, for example, an optical method, a rotation method, or a fluid method.

In the above embodiments, the physical quantity sensor that detects the angular velocity and the acceleration is described as an example, but the failure diagnosis circuit of the disclosure is applicable to any physical quantity sensor that operates based on a reference voltage generated by a reference voltage generation circuit such as a regulator. Examples of such a physical quantity sensor include a fiber optic gyroscope (FOG), a temperature sensor, a pressure sensor, a gas sensor, and a humidity sensor. The failure diagnosis circuit of the disclosure is applicable not only to a physical quantity sensor but also to a vibrator device. Examples of the vibrator device include a vibration-type physical quantity sensor in which a physical quantity detection element vibrates and an oscillator that generates an oscillation signal by oscillating a vibrator. Examples of such an oscillator include an oscillator including a quartz crystal vibrator and a silicon micro electro mechanical systems (MEMS) resonator. Such a vibrator device can implement high reliability by including the failure diagnosis circuit of the disclosure.

The embodiments and the modifications described above are examples, and the disclosure is not limited thereto. For example, the embodiments and the modifications may be combined as appropriate.

The disclosure includes configurations that are substantially identical to the configurations described in the embodiments, for example, configurations having the same function, method, and result, or configurations having the same object and effect. The disclosure includes configurations obtained by replacing non-essential portions of the configurations described in the embodiments. The disclosure includes configurations that can obtain the same function and effect and configurations that can accomplish the same object as the configurations described in the embodiments. The disclosure includes configurations obtained by adding a known technique to the configurations described in the embodiments.

The following contents are derived from the embodiments and the modifications described above.

One aspect of a failure diagnosis circuit is a failure diagnosis circuit that performs failure diagnosis on a reference voltage generation circuit, in which
the failure diagnosis circuit monitors a reference voltage supplied from the reference voltage generation circuit to a first circuit, and diagnoses that the reference voltage generation circuit fails when a state in which the reference voltage is not within a predetermined range continues for a predetermined time.

The failure diagnosis circuit diagnoses that the reference voltage generation circuit fails when the state in which the reference voltage is not within the predetermined range continues for the predetermined time.

When the reference voltage temporarily fluctuates and falls outside the predetermined range, the failure diagnosis circuit does not diagnose that the reference voltage generation circuit fails unless the state continues for the predetermined time. Accordingly, even when the reference voltage temporarily fluctuates, the failure diagnosis circuit can reduce the possibility of erroneously diagnosing that the reference voltage generation circuit fails. For example, even when the supply capability of the reference voltage by the reference voltage generation circuit is relatively low, since the possibility of erroneous determination by the failure diagnosis circuit is reduced, a size of the reference voltage generation circuit can be reduced.

In one aspect of the failure diagnosis circuit,
the first circuit may be an analog-digital conversion circuit that converts an analog signal into a digital signal.

According to the failure diagnosis circuit, even when the reference voltage temporarily fluctuates according to the operation of the analog-digital conversion circuit, it is possible to reduce the possibility of erroneously determining that the reference voltage generation circuit fails.

In one aspect of the failure diagnosis circuit, the first circuit may be a physical quantity signal processing circuit that outputs a drive signal for driving a physical quantity detection element for detecting a physical quantity, and generates a detection signal corresponding to the physical quantity based on an output signal of the physical quantity detection element.

Even when the reference voltage temporarily fluctuates according to the operation of the physical quantity signal processing circuit, the failure diagnosis circuit can reduce the possibility of erroneously determining that the reference voltage generation circuit fails.

In one aspect of the failure diagnosis circuit,
the reference voltage may temporarily fluctuate in at least one of a timing at which the analog-digital conversion circuit starts sampling of the analog signal and a timing at which the analog-digital conversion circuit ends the sampling.

Even when the reference voltage temporarily fluctuates at the timing at which the analog-digital conversion circuit starts the sampling of the analog signal or at the timing at which the analog-digital conversion circuit ends the sampling, the failure diagnosis circuit can reduce the possibility of erroneously determining that the reference voltage generation circuit fails.

In one aspect of the failure diagnosis circuit, the reference voltage may temporarily fluctuate in at least one timing of a rising edge and a falling edge of the drive signal.

Even when the reference voltage temporarily fluctuates at the rising edge or the falling edge of the drive signal of the physical quantity detection element, the failure diagnosis circuit can reduce the possibility of erroneously determining that the reference voltage generation circuit fails.

In one aspect of the failure diagnosis circuit,
the reference voltage may temporarily fluctuate in at least one timing of a rising edge and a falling edge of a control signal for controlling the physical quantity signal processing circuit.

Even when the reference voltage temporarily fluctuates at the rising edge or the falling edge of the control signal of the physical quantity signal processing circuit, the failure diagnosis circuit can reduce the possibility of erroneously determining that the reference voltage generation circuit fails.

One aspect of the failure diagnosis circuit may include:
an abnormality determination circuit configured to determine whether the reference voltage is abnormal and output an abnormality determination signal indicating a determination result; and
a failure diagnosis signal output circuit configured to diagnose whether the reference voltage generation circuit fails based on the abnormality determination signal, and output a failure diagnosis signal indicating a diagnosis result, in which
the failure diagnosis signal output circuit may diagnose that the reference voltage generation circuit fails when the abnormality determination signal continues for a predetermined time and the reference voltage is abnormal.

When the reference voltage temporarily fluctuates, even if the abnormality determination circuit temporarily outputs the abnormality determination signal indicating that the reference voltage is abnormal, the failure diagnosis circuit can reduce the possibility that the failure diagnosis signal output circuit erroneously outputs the failure diagnosis signal indicating that the reference voltage generation circuit fails.

When the reference voltage generation circuit fails, the failure diagnosis signal output circuit can promptly output the failure diagnosis signal indicating that the reference voltage generation circuit fails. Therefore, for example, the failure diagnosis circuit can satisfy a request for a short FTTI in an upper system.

One aspect of a vibrator device includes:
one aspect of the failure diagnosis circuit.

Since the vibrator device includes the failure diagnosis circuit capable of reducing the possibility of erroneously diagnosing that the reference voltage generation circuit fails even when the reference voltage temporarily fluctuates, high reliability can be implemented.

One aspect of a physical quantity sensor includes:
one aspect of the failure diagnosis circuit.

Since the physical quantity sensor includes the failure diagnosis circuit capable of reducing the possibility of erroneously diagnosing that the reference voltage generation circuit fails even when the reference voltage temporarily fluctuates, high reliability can be implemented.

What is claimed is:

1. A failure diagnosis circuit that performs failure diagnosis on a reference voltage generation circuit, wherein
the failure diagnosis circuit monitors a reference voltage supplied from the reference voltage generation circuit to a first circuit, and diagnoses that the reference voltage generation circuit fails when a state in which the reference voltage is not within a predetermined range continues for a predetermined time.

2. The failure diagnosis circuit according to claim 1, wherein
the first circuit is an analog-digital conversion circuit that converts an analog signal into a digital signal.

3. The failure diagnosis circuit according to claim 1, wherein
the first circuit is a physical quantity signal processing circuit that outputs a drive signal for driving a physical quantity detection element for detecting a physical quantity, and generates a detection signal corresponding to the physical quantity based on an output signal of the physical quantity detection element.

4. The failure diagnosis circuit according to claim 2, wherein
the reference voltage temporarily fluctuates in at least one of a timing at which the analog-digital conversion circuit starts sampling of the analog signal and a timing at which the analog-digital conversion circuit ends the sampling.

5. The failure diagnosis circuit according to claim 3, wherein
the reference voltage temporarily fluctuates in at least one timing of a rising edge and a falling edge of the drive signal.

6. The failure diagnosis circuit according to claim 3, wherein
the reference voltage temporarily fluctuates in at least one timing of a rising edge and a falling edge of a control signal for controlling the physical quantity signal processing circuit.

7. The failure diagnosis circuit according to claim 1, further comprising:
an abnormality determination circuit configured to determine whether the reference voltage is abnormal and output an abnormality determination signal indicating a determination result; and
a failure diagnosis signal output circuit configured to diagnose whether the reference voltage generation circuit fails based on the abnormality determination signal, and output a failure diagnosis signal indicating a diagnosis result, wherein
the failure diagnosis signal output circuit diagnoses that the reference voltage generation circuit fails when the abnormality determination signal continues for a predetermined time and the reference voltage is abnormal.

8. A vibrator device comprising:
the failure diagnosis circuit according to claim 1.

9. A physical quantity sensor comprising:
the failure diagnosis circuit according to claim 1.
